(19) United States
(12) Patent Application Publication
(10) Pub. No.: US 2025/0261506 A1
(43) Pub. Date: Aug. 14, 2025

(54) CURABLE HIGH REFRACTIVE INDEX INK COMPOSITIONS WITH WATER-SEQUESTRATION AGENTS

(71) Applicant: 3M INNOVATIVE PROPERTIES COMPANY, St. Paul, MN (US)

(72) Inventors: Kyung Hwan Yoon, Gyeonggi-do (KR); Yungjung Cho, Gyeonggi-do (KR); Evan L. Schwartz, Vadnais Heights, MN (US)

(21) Appl. No.: 18/854,806

(22) PCT Filed: Apr. 24, 2023
(86) PCT No.: PCT/IB2023/054199

§ 371 Date: Oct. 7, 2024

Related U.S. Application Data
(60) Provisional application No. 63/336,363, filed on Apr. 29, 2022.

(51) Int. Cl. H10K 50/84; C09D 11/101; C09D 11/107; C09D 11/30

(52) U.S. Cl. CPC H10K 50/846; C09D 11/101; C09D 11/107; C09D 11/30

(57) ABSTRACT

Curable ink compositions include a (meth)acrylate-based component that upon curing forms a matrix, and a water sequestration component. The water sequestration component is an epoxy/anhydride reactive pair. At least one of the reactive pair is co-curable with the (meth)acrylate component. The reactive pair sequesters water by a 2-step mechanism, the water reacts with an anhydride to form an acid, and the acid reacts with an epoxy. Since at least one of the epoxy and anhydride are bonded to the (meth)acrylate matrix, this reaction causes irreversible water uptake by the matrix. The ink composition is inkjet printable, has a refractive index of 1.55 or greater and is optically clear. The cured matrix has a water uptake of at least 2% by weight upon exposure to 85° C./85% Relative Humidity for 7 days.

### SUMMARY

Disclosed herein are curable high refractive index compositions that contain water sequestration agents. The water sequestration agents aid in preventing the migration of water through the cured ink compositions. Also disclosed are articles that contain layers prepared from the curable high refractive index ink compositions.

In some embodiments, the curable ink composition comprises a (meth)acrylate-based component capable of curing to form a (meth)acrylate-based matrix, and a water sequestration component. The curable (meth)acrylate-based component comprises at least one aromatic (meth)acrylate, at least one multifunctional (meth)acrylate with heteroaromatic groups, fused aromatic groups, heteroalkylene groups, or a group containing both heteroalkylene and aromatic groups, and a photoinitiator. The water sequestration component is a reactive pair, of epoxy-functional and anhydride-functional parts. The water sequestration component comprises at least one co-curable moiety comprising an epoxy-functional (meth)acrylate, an anhydride-functional ethylenically unsaturated compound, or both; and optionally a non-curable epoxy moiety, a non-curable anhydride moiety, or both. Upon curing, the ink composition forms a (meth)acrylate matrix with epoxy-functional groups, anhydride-functional groups, or both. The matrix is capable of water sequestration whereby an anhydride group either attached to the matrix or not reacts with water to form an acid that reacts with an epoxy-functional group. As stated above, either one or both of the epoxy and anhydride groups are attached to the matrix. Therefore, this reaction creates irreversible water uptake by the (meth)acrylate-based matrix. The ink composition is inkjet printable, having a viscosity of 30 centipoise or less at a temperature of from room temperature to 35° C., and is free from solvents. The ink composition when disposed and cured has a refractive index of 1.55 or greater and is optically clear, has an irreversible water uptake of at least 2% by weight upon exposure to 85° C./85% Relative Humidity for 7 days.

In some embodiments, articles of this disclosure comprise a substrate with a first major surface and a second major surface and a cured organic layer adjacent to at least a portion of the second major surface of the substrate, where the cured organic layer comprises a crosslinked (meth)acrylate-based layer containing epoxy-functional groups, anhydride-functional groups, or both, has a refractive index of 1.55 or greater, and is optically clear. The cured organic layer may comprise a non-curable epoxy moiety, a non-curable anhydride moiety, or both, such that the cured organic layer has a water sequestration component. The water sequestration component is a reactive pair, the reactive pair being epoxy-functional and anhydride-functional parts. The water sequestering component creates irreversible water uptake by the (meth)acrylate matrix as described above. The irreversible water uptake is at least 2% by weight upon exposure to 85° C./85% Relative Humidity for 7 days.

### BRIEF DESCRIPTION OF THE DRAWINGS

The present application may be more completely understood in consideration of the following detailed description of various embodiments of the disclosure in connection with the accompanying drawings.

FIG. 1 is a cross-sectional view of an article of this disclosure.

FIG. 2 is a cross-sectional view of a test article used in the Examples section.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Optical devices are becoming more and more complex, which impacts what materials can used in them. In particular, organic polymeric materials have found widespread use in optical devices, however, they still must meet the stringent requirements and demands needed for performance.

For example, thin organic polymeric films are desirable for a wide range of uses in optical devices, as adhesives, protective layers, spacer layers, and the like. As articles have become more complex, the physical demands upon these layers have increased. For example, as optical devices have become more compact, they often include additional layers, resulting in a growing need for thinner layers. At the same time, since the layers are thinner, the layers also need to be more precise. For example, a thin spacer layer (of 1 micrometer thickness) needs to be level and free of gaps and holes in order to provide the proper spacing function. This requires deposition of the organic layer in a precise and consistent manner.

Additionally, not only do these layers have to fulfill their physical role (adhesion, protection, spacing, and the like) they must also provide the requisite optical properties. Among the properties that are becoming increasingly important is refractive index. As light travels through the layers of a multilayer article, it encounters the interface between layers. If the refractive indices of the layers are different, light can be refracted. Therefore, to minimize this refraction, matching of the refractive indices of layers within a multilayer article is desirable.

An example of an optical device that utilizes thin film layers are OLED (organic light-emitting diode) devices. In particular, the organic light-emitting devices are susceptible to degradation from the permeation of certain liquids and gases, such as water vapor and oxygen. To reduce permeability to these liquids and gases, barrier coatings are applied to the OLED device, which is known in the art as thin film encapsulation. Typically, these barrier coatings require a high refractive index to match with other layers in the devices.

Typically, the organic thin film layers are a cured organic matrix. Because the layers are very thin the barrier layers may have difficulty preventing the transport of water through the barrier layer, especially for example in humid environments. Water can be detrimental to devices such as OLEDs, so it is desirable that the barrier layer have an enhanced ability to prevent water migration. One method is for the organic matrix to absorb the water. Various techniques can be used to make organic thin film layers water absorptive to prevent the passage of water through the organic thin film layer. However, many of these techniques can alter the desirable and necessary properties of the organic thin film layer, such as the optical properties. Also, many of the materials typically used to absorb the water in organic matrices (often referred to as water scavengers) can themselves release small molecules that are detrimental to the organic layer and/or to the device. For example, oxazoladines or alkoxy silanes can be used as water scavengers, but these molecules form ketones and alcohols respectively, and these small molecules are problematic materials to generate within organic thin film layers. Therefore, a need remains for methods of water scavenging in organic thin film layers.

In this disclosure, a water scavenging methodology is described that is a water sequestering methodology. This sequestering methodology is a two-step process involving an anhydride/epoxy reactive pair. The process utilizes anhydride-functional groups that react with water to form acid groups, and the acid groups react with epoxy groups. At least one of the anhydride and epoxy are cured into the (meth)acrylate matrix, so the result of this 2-step reaction is the trapping or sequestering of the water within the matrix without the generation of any small molecules.

The term “(meth)acrylate” refers to monomeric acrylic or methacrylic esters of alcohols. Acrylate and methacrylate monomers or oligomers are referred to collectively herein as “(meth)acrylates”. Materials referred to as “(meth)acrylate functional” are materials that contain one or more (meth)acrylate groups. The term “(meth)acrylate-based refers to a composition or a layer that contains (meth)acrylates and may contain additional (meth)acrylate co-reactive materials.

The terms “room temperature” and “ambient temperature” are used interchangeably to mean temperatures in the range of 20° C. to 25° C.

The term “adjacent” as used herein when referring to two layers means that the two layers are in proximity with one another with no intervening open space between them. They may be in direct contact with one another (e.g. laminated together) or there may be intervening layers.

The terms “polymer” and “macromolecule” are used herein consistent with their common usage in chemistry. Polymers and macromolecules are composed of many repeated subunits. As used herein, the term “macromolecule” is used to describe a group attached to a monomer that has multiple repeating units. The term “polymer” is used to describe the resultant material formed from a polymerization reaction.

The term “alkyl” refers to a monovalent group that is a radical of an alkane, which is a saturated hydrocarbon. The alkyl can be linear, branched, cyclic, or combinations thereof and typically has 1 to 20 carbon atoms. In some embodiments, the alkyl group contains 1 to 18, 1 to 12, 1 to 10, 1 to 8, 1 to 6, or 1 to 4 carbon atoms. Examples of alkyl groups include, but are not limited to, methyl, ethyl, n-propyl, isopropyl, n-butyl, isobutyl, tert-butyl, n-pentyl, n-hexyl, cyclohexyl, n-heptyl, n-octyl, and ethylhexyl.

The term “aryl” refers to a monovalent group that is aromatic and carbocyclic. The aryl can have one to five rings that are connected to or fused to the aromatic ring. The other ring structures can be aromatic, non-aromatic, or combinations thereof. Examples of aryl groups include, but are not limited to, phenyl, biphenyl, terphenyl, anthryl, naphthyl, acenaphthyl, anthraquinonyl, phenanthryl, anthracenyl, pyrenyl, perylenyl, and fluorenyl.

The term “alkylene” refers to a divalent group that is a radical of an alkane. The alkylene can be straight-chained, branched, cyclic, or combinations thereof. The alkylene often has 1 to 20 carbon atoms. In some embodiments, the alkylene contains 1 to 18, 1 to 12, 1 to 10, 1 to 8, 1 to 6, or 1 to 4 carbon atoms. The radical centers of the alkylene can be on the same carbon atom (i.e., an alkylidene) or on different carbon atoms.

The term “heteroalkylene” refers to a divalent group that includes at least two alkylene groups connected by a thio, oxy, or —NR— where R is alkyl. The heteroalkylene can be linear, branched, cyclic, substituted with alkyl groups, or combinations thereof. Some heteroalkylenes are poloxyyalkylenes where the heteroatom is oxygen such as for example,
—CH₂CH₂(OCH₂CH₂)ₙOCH₂CH₂—.

The terms “free radically polymerizable” and “ethylenically unsaturated” are used interchangeably and refer to a reactive group which contains a carbon-carbon double bond which is able to be polymerized via a free radical polymerization mechanism.

Unless otherwise indicated, “optically transparent” refers to a layer, film, or article that has a high light transmittance over at least a portion of the visible light spectrum (about 400 to about 700 nm). Typically, optically transparent layers, films, or articles have a luminous transmission of at least 80%.

Unless otherwise indicated, “optically clear” refers to a layer, film, or article that has a high light transmittance over at least a portion of the visible light spectrum (about 400 to about 700 nm), and that exhibits low haze. Typically, optically clear layers, films, or articles have visible light transmittance values of at least 80%, often at least 90%, and haze values of 5% or less, often 2% or less.

Disclosed herein are curable compositions that are printable, and thus are described as inks. The curable compositions need not be used as inks, that is to say that they need not be printed and then cured, the curable compositions can be delivered to substrate surfaces in a wide variety of ways, but they are capable of being printed. The terms “curable composition” and “ink” are used interchangeably in this disclosure. In particular, the printable compositions of this disclosure are typically capable of being inkjet printed, which means that they have the proper viscosity and other attributes to be inkjet printed. The term “inkjet printable” is not a process description or limitation, but rather is a material description, meaning that the curable compositions are capable of being inkjet printed, and not that the compositions necessarily have been inkjet printed. This is akin to the expression “hot melt processable”, which means that a composition is capable of being hot melt processed but does not mean that the composition has been hot melt processed.

The curable ink compositions comprise a (meth)acrylate-based component capable of curing to form a (meth)acrylate-based matrix and a water sequestration component. The (meth)acrylate-based component comprises: at least one aromatic (meth)acrylate: at least one multifunctional (meth)acrylate where the multifunctional (meth)acrylate either comprises heteroaromatic groups, fused aromatic groups, heteroalkylene groups, or a group containing both heteroalkylene and aromatic groups; and a photoinitiator. The (meth)acrylate-based component, upon curing forms a crosslinked matrix.

The water sequestration component comprises a reactive pair, the reactive pair being epoxy-functional and anhydride-functional parts. The water sequestration component comprises: at least one co-curable moiety comprising an epoxy-functional (meth)acrylate, an anhydride-functional ethylenically unsaturated compound, or both; and optionally a non-curable epoxy moiety, a non-curable anhydride moiety, or both. In this way, at least one of the reactive pair (anhydride or epoxy) is cured into the (meth)acrylate matrix. As described above, water sequestration by the reactive pair occurs by reaction of water with an anhydride group to form an acid, where the anhydride group is either cured into the (meth)acrylate matrix or not. The acid then reacts with an epoxy group. Again, the epoxy group may be cured into the (meth)acrylate matrix or not, as long as at least one of the anhydride or epoxy groups are cured into the (meth)acrylate matrix. In this way, the water is irreversibly attached to the (meth)acrylate matrix and no small molecule byproducts are generated. This process is called water sequestration because the free water molecules become, through this process incorporated into the matrix, thus creating irreversible water uptake.

The ink compositions have a variety of desirable properties including being solvent free and inkjet printable, having a viscosity of 30 centipoise or less at a temperature of from room temperature to 35° C., and when disposed and cured forms an organic layer having a refractive index of 1.55 or greater and is optically clear. Additionally, the cured organic layer has an irreversible water uptake of at least 2% by weight upon exposure to 85° C./85% Relative Humidity for 7 days.

The curable ink compositions comprise a (meth)acrylate-based component and water sequestering component. As mentioned above, the (meth)acrylate-based component comprises: at least one aromatic (meth)acrylate; at least one multifunctional (meth)acrylate where the multifunctional (meth)acrylate either comprises heteroaromatic groups, fused aromatic groups, heteroalkylene groups, or a group containing both heteroalkylene and aromatic groups; and a photoinitiator. A wide variety of aromatic (meth)acrylate monomers are suitable for use in the curable ink compositions of this disclosure. Typically, these aromatic (meth)acrylate monomers are monofunctional. A single monofunctional (meth)acrylate monomer may be used or a mixture of monofunctional (meth)acrylate monomers may be used. Generally, the at least one monofunctional (meth)acrylate comprises a compound of Formula I (shown below):

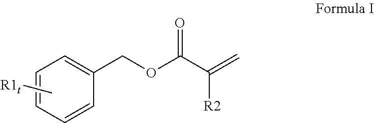

wherein at least one R1 comprises an aromatic substituent, t is an integer from 1 to 4, and R2 is hydrogen or methyl.

A wide variety of aromatic substituents are suitable for the R1 group or groups. Typically, the at least one aromatic substituent R1 comprises a substituted or unsubstituted aromatic group of the type —CH₂—Ar, or a heteroatom linked aromatic group of the type —X—Ar, where X is S or O, and each Ar is independently a substituted or unsubstituted phenyl group, a fused aromatic group, or 2 or more alkyl group-linked phenyl or substituted phenyl or substituted phenyl groups.

Thus, the R1 group or groups may comprise various aromatic substituents such as:

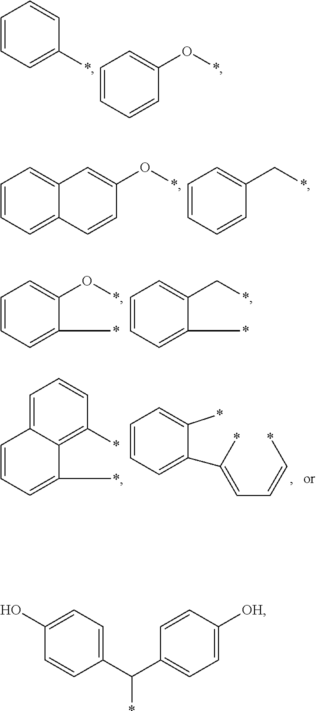

or *—S—Ar.

The aromatic substituent R1 is generally bonded to the aromatic ring of the benzyl group by at least one divalent (e.g. alkylene or ether) linking group. In some embodiments, the aromatic substituent R1 is bonded to the aromatic benzyl ring by two or more divalent (e.g. alkylene or ether) linking groups. Each * denotes the point(s) of attachment to the aromatic ring of Formula I; and Ar is a substituted or unsubstituted phenyl group, a fused aromatic group, or 2 or more alkyl group-linked phenyl or substituted phenyl groups.

In some favored embodiments, t is 1. Representative structures for Formula I thus include:

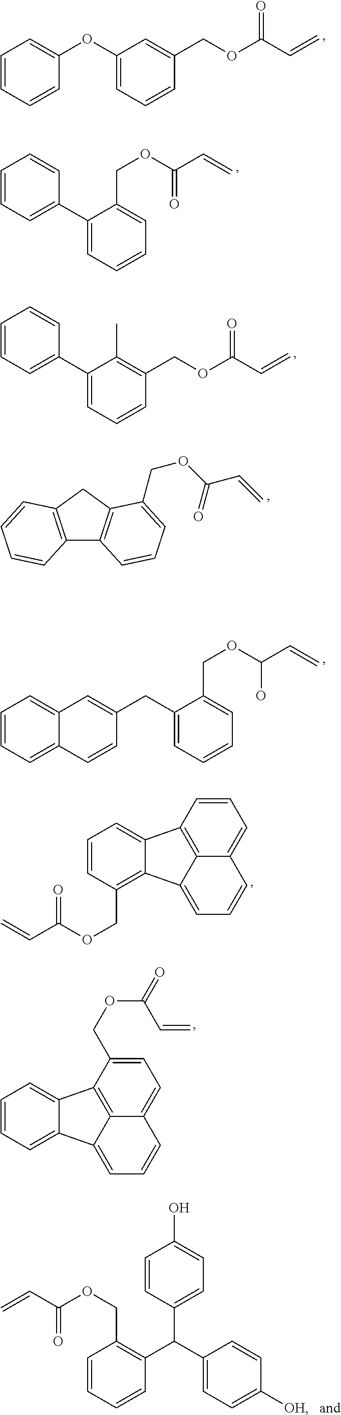

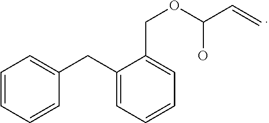 [SMILES: C=CC(O)OCc1ccccc1Cc1ccccc1 ; "."]

In some of the embodiments where t is 1 and the R1 group is *—S—Ar, the compounds can have the general structure of Formula IA:

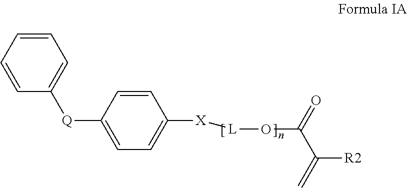

where R2 is H or CH₃, X is O, S, or a single bond, Q is O, S, SiR₂ where R is an alkyl group, a carbonyl group (C═O), an amino group NR where R is hydrogen or an alkyl, or an SO₂ group, n ranges from 0 to 10 (e.g. n is 0, 1, 2, 3, 4, 5, 6, 7, 8, 9, or 10), and L is an alkylene group having 1 to 5 carbon atoms, optionally substituted with hydroxyl groups.

One particularly suitable monomer of Formula IA is one in which R2 is a hydrogen, n is 1, L is a —CH₂— group, X is a single bond, and Q is a sulfur. This monomer is shown below as Formula IB:

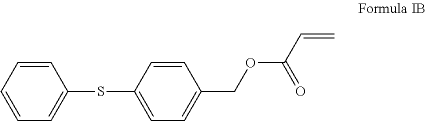 [SMILES: C=CC(=O)OCc1ccc(Sc2ccccc2)cc1]

While similar compounds to this monomer have been reported in the literature, for example in the Korean Patent Publication No. 101,254,325B1, it has been found that this monomer has particularly desirable viscosity and refractive index features. In particular it has been found that the monomer of Formula III has a viscosity of less than 40 centipoise at 25° C., even a viscosity of 13 centipoise at 25° C., and a refractive index when uncured of less than 1.630, or even less than 1.620.

In other embodiments of the monomers of Formula I, t is greater than 1. In one embodiment, t is 3. One representative structure is:

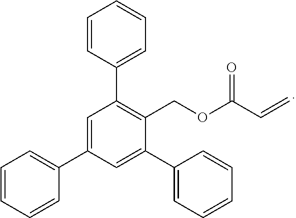 [SMILES: C=CC(=O)OCc1c(-c2ccccc2)cc(-c2ccccc2)cc1-c1ccccc1]

Various aromatic alcohols from Sigma-Aldrich are available as starting materials that can be converted to (meth)acrylates by reacting such materials with (meth)acrylic acid or (meth)acrylic acid derivatives. Particularly suitable monofunctional (meth)acrylate monomers include biphenylmethyl acrylate (where R1 is phenyl group) commercially available from Miwon Specialty Chemicals, Exton, PA as MIRAMER M1192 or MIRAMER M1192H, and the monomer of Formula III, the synthesis of which is presented in the Examples section.

The amount of aromatic (meth)acrylate monomer employed in the curable ink composition can vary. By “the aromatic (meth)acrylate monomer”, refers to all of the aromatic (meth)acrylate monomers present if more than one aromatic (meth)acrylate monomer is used. In some embodiments, the curable ink compositions comprise at least 20% by weight or greater of the aromatic (meth)acrylate monomer. In other embodiments, the curable ink composition comprises up to 65% by weight of the aromatic (meth)acrylate monomer. As mentioned above, typically the aromatic (meth)acrylate monomer is a monofunctional (meth)acrylate.

In some embodiments, the aromatic (meth)acrylate monomer has a refractive index greater than 1.50 (e.g. at least 1.51 or 1.52) and may have a refractive index of greater than 1.60. Generally, these aromatic (meth)acrylate monomers are non-halogenated (e.g. non-brominated). In some embodiments, the aromatic (meth)acrylate monomers have a refractive index of at least 1.53, 1.54, 1.55, 1.56, 1.57, 1.58, 1.59, 1.60, or 1.61 and typically no greater than 1.65.

The curable ink compositions of this disclosure also include at least one multifunctional (meth)acrylate of general Formula II:

(H₂C═CR2-(CO)—O-)ₙA Formula II
where R2 is hydrogen or methyl, (CO) is a carbonyl group C═O, A is an n-valent group comprising a heteroaromatic, fused aromatic, or a group containing both heteroalkylene and aromatic groups, and n is an integer of 2 or greater. In some embodiments, the multifunctional (meth)acrylate is difunctional (n=2), in other embodiments, the multifunctional (meth)acrylate is trifunctional (n=3). Higher functional multifunctional (meth)acrylates are also possible.

Examples of heteroaromatic groups include thiadiazole groups, thiazole groups, and thiophene groups. Examples of fused aromatic groups include naphthyl groups, anthracenyl groups, and fluorenyl groups. Examples of heteroalkylene groups include polyethylene oxide groups, polypropylene oxide groups, polythioether groups, and the like. Examples of groups containing both heteroalkylene and aromatic groups include ones with the difunctional alkylene groups with 2-10 carbon atoms, and have from 1-10 repeat units, and contain difunctional aromatic groups such as phenylene, benzylene, or linked benzylene groups.

In some embodiments, it may be desirable to use multifunctional (meth)acrylate monomers that have functionalities higher than 2. One particularly suitable trifunctional (meth)acrylate is TMPTA (trimethylolpropane triacrylate) that is commercially available under the trade designation “MIRAMER M300” from Miwon Specialty Chemical Co., Ltd. Yongin, Korea.

Since the multifunctional (meth)acrylate monomers have functionalities of 2 or greater, these monomers serve as crosslinking agents and crosslink the forming polymer. The amount of multifunctional (meth)acrylate monomer is controlled to prevent the polymer from becoming inflexible. Typically, the curable ink composition comprises less than 65% by weight of the multifunctional (meth)acrylate monomer or monomers, and at least 10% by weight of the multifunctional (meth)acrylate monomer or monomers. In some embodiments, the multifunctional (meth)acrylate monomer or monomers are present in an amount of from 15-35% by weight.

The (meth)acrylate component also comprises at least one photoinitiator, meaning that the initiator is activated by light, generally ultraviolet (UV) light, although other light sources could be used with the appropriate choice of intiator, such a visible light initiators, infrared light initiators, and the like. Typically, UV photoinitiators are used. Photoinitiators are well understood by one of skill in the art of (meth)acrylate polymerization. Examples of suitable free radical photoinitiators include IRGACURE 4265, IRGACURE 184, IRGACURE 651, IRGACURE 1173, IRGACURE 819, IRGACURE TPO, IRGACURE TPO-L, commercially available from BASF, Charlotte, NC.

Generally, the photoinitiator is used in amounts of 0.01 to 10 parts by weight, more typically 0.1 to 2.0, parts by weight relative to 100 parts by weight of total reactive components.

The curable ink compositions also comprise a water sequestration component. As described above, the water sequestration component is an anhydride/epoxy reactive pair. At least one of the components of the reactive pair is co-curable with the (meth)acrylate component described above. By this it is meant that at least one of the reactive pair is a compound with an ethylenically unsaturated group such that it co-cures with the (meth)acrylate components and becomes part of the (meth)acrylate matrix. The water sequestration component may also comprise a non-curable epoxy or anhydride-functional moiety. If both reactive pair components are co-curable there is no need for a non-curable epoxy or anhydride-functional moiety. In many embodiments, a non-curable epoxy or anhydride-functional moiety.

The reaction pair of the water sequestration component comprises at least one epoxy-functional moiety. The at least one epoxy-functional moiety may comprise a co-curable epoxy-functional moiety, a non-curable epoxy-functional moiety, or a combination thereof. In many embodiments, the epoxy-functional moiety is a co-curable moiety. Epoxy-functional (meth)acrylates are particularly suitable co-curable epoxy moieties. Suitable epoxy (meth)acrylates include those described by Formula III:

H₂C═CR2-(CO)—O—CH₂—B Formula III
where R2 is hydrogen or methyl; (CO) is a carbonyl group C═O; and B is divalent group comprising an epoxy-functional alkylene or heteroalkylene group. Examples of suitable epoxy (meth)acrylates include the commercially available 3,4-epoxycyclohexylmethyl methacrylate TTA-15 from Jiangsu Tetra New Material Technology.

The reaction pair of the water sequestration component also comprises at least one anhydride-functional moiety. The at least one anhydride may comprise a co-curable anhydride, a non-curable anhydride, or combination thereof.

In some embodiments, the anhydride is a co-polymerizable anhydride comprising a (meth)acrylate-functional anhydride of Formula IV:

H₂C═CR2-(CO)—O—(CO)—R2C═CH₂ Formula IV
where R2 is hydrogen or methyl; (CO) is a carbonyl group C═O. Examples of such an anhydride include methacrylic anhydride. In other embodiments, the co-polymerizable anhydride comprises an ethylenically unsaturated anhydride such as maleic anhydride.

In some embodiments, the anhydride is a non-curable anhydride. Examples of non-curable anhydrides include aromatic anhydrides and aliphatic anhydrides. Aromatic anhydrides are particularly suitable as they typically have higher refractive indices than aliphatic anhydrides. Higher refractive index synthons are desirable to form a higher refractive index matrix, and since the anhydride becomes incorporated into the matrix higher refractive index anhydrides may be more desirable. Suitable aromatic anhydrides include benzoic anhydride and phthalic anhydride. Aliphatic anhydrides include NBA (5-Norbornene-2,3-dicarboxylic anhydride).

In some especially suitable curable ink compositions, the water sequestration component comprises a co-curable epoxy-functional (meth)acrylate and a non-curable anhydride. While not wishing to be bound by theory, it is believed that the use of a non-curable anhydride provides increased mobility within the (meth)acrylate matrix to permit easier access of the anhydride to any water that enters the matrix.

The amount of each of the parts of the water sequestration component can vary widely. Typically, in embodiments containing epoxy (meth)acrylate moieties, the epoxy (meth)acrylate is present in an amount of 0.075-45% by weight of the total weight of the curable ink composition. In these embodiments, the non-curable anhydride comprises 0.005-18% by weight of the total weight of the curable ink composition.

Also disclosed herein are articles. In some embodiments, the articles comprise a substrate with a first major surface and a second major surface, and a cured organic layer adjacent to at least a portion of the second major surface of the substrate. The cured organic layer comprises a crosslinked (meth)acrylate-based layer containing epoxy-functional groups, anhydride-functional groups, or both, has a refractive index of 1.55 or greater, and is optically clear. The cured organic layer optionally comprises a non-curable epoxy moiety, a non-curable anhydride moiety, or both, such that the cured organic layer has a water sequestration component. The water sequestration component has been described above and is a reactive pair, the reactive pair being epoxy-functional and anhydride-functional parts. An anhydride group either cured into the (meth)acrylate matrix or a non-curable moiety, upon reacting with water forms acid-functional groups that react with epoxy-functional groups either cured into the (meth)acrylate matrix or a non-curable moiety. At least one of the epoxy-functional or anhydride-functional groups is cured into the (meth)acrylate matrix, thereby creating irreversible water uptake of the (meth)acrylate-based matrix, where the irreversible water uptake is at least 2% by weight upon exposure to 85° C./85% Relative Humidity for 7 days.

The cured organic layer is formed by curing a curable ink composition that has been disposed and cured on at least a portion of the second major surface of the substrate. The curable ink compositions have been described above and comprise a (meth)acrylate-based component capable of curing to form a (meth)acrylate-based matrix, and a water sequestration component. As mentioned above, the (meth)acrylate-based component comprises at least one aromatic (meth)acrylate; at least one multifunctional (meth)acrylate with heteroaromatic groups, fused aromatic groups, heteroalkylene groups, or a group containing both heteroalkylene and aromatic groups; and a photoinitiator. Each of these components is described in detail above. The water sequestration component comprises a reactive pair, the reactive pair being epoxy-functional and anhydride-functional parts. The water sequestration component comprises: at least one co-curable moiety comprising an epoxy-functional (meth)acrylate, an anhydride-functional ethylenically unsaturated compound, or both; and optionally a non-curable epoxy moiety, a non-curable anhydride moiety, or both. The curable ink composition is inkjet printable having a viscosity of 30 centipoise or less at a temperature of from room temperature to 35° C. and is free from solvents.

The cured organic layer can have a wide range of thicknesses. Typically, the cured organic layer is a thin layer. As mentioned above, the curable ink composition can be disposed on the substrate in a wide variety of techniques including but not limited to printing techniques, where inkjet printing is particularly suitable for forming thin layers. In some embodiments, the cured organic layer has a thickness of from 1-16 micrometers.

As mentioned above, the cured organic layer is adjacent to the second major surface of the substrate. A wide range of substrates are suitable. In some embodiments, the article comprises an electronic device and the substrate comprises an optical electronic component. Examples of suitable optical electronic component comprises at least one of an organic light emitting diode, a quantum dot light emitting diode, a micro light emitting diode, or a quantum nanorod electronic device. An example of a particularly suitable optical electronic component is an organic light emitting diode (OLED). The cured organic layer may be disposed on the optical electronic component, or there may be one or more intervening layers.

Also disclosed herein are methods for preparing articles, especially optical articles. These methods comprise, providing a substrate with a first major surface and a second major surface, providing a curable ink composition, disposing the curable ink composition on the second major surface of the substrate to form a curable layer, and curing the curable layer to form a cured organic layer. The cured organic layer has a refractive index of 1.55 or greater and is optically clear. Typically, the cured organic layer has a thickness of from 1-16 micrometers.

In many embodiments, the disposing of the curable ink composition on the second major surface of the substrate to form a curable layer comprises printing, especially inkjet printing. As described above, inkjet printing has a variety of desirable features that make it particularly suitable for preparing the curable layer, including the ability to deposit precise patterns on complex substrates and form a uniform coating.

The curable ink compositions used in this method are the curable ink compositions described above. Since the curable ink compositions include a photoinitiator, curing of the curable layer comprises photo curing. The nature of the photoinitiator determines the curing conditions, i.e. radiation wavelength used, duration of the exposure to radiation, etc.

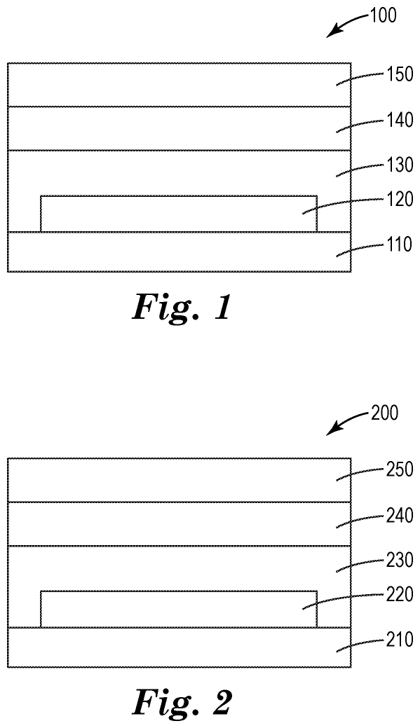

An example of an article of this disclosure is shown in FIG. 1. FIG. 1 shows an OLED device. The OLED device has base layer 110, with OLED 120 disposed on this base layer. Inorganic barrier layer (typically aluminum oxide) 130, the cured organic layer of this disclosure 140, and another inorganic barrier layer (typically aluminum oxide) 150.

### EXAMPLES

These examples are merely for illustrative purposes only and are not meant to be limiting on the scope of the appended claims. All parts, percentages, ratios, etc. in the examples and the rest of the specification are by weight, unless noted otherwise. The following abbreviations are used: mm=millimeters; cm=centimeters; nm=nanometers; mL=milliliters; RPM=revolutions per minute; sec=seconds; min=minutes; J=Joules; W=Watts; CTH=Controlled Temperature and Humidity. The terms “weight %”, “% by weight”, and “wt %” are used interchangeably.

### Materials Used in the Examples

| Abbreviation | Description and Source |
|---|---|
| BPMA | Biphenylmethyl acrylate, obtained under the trade designation |
| | “Miramer M1192H” from Miwon Specialty Chemical Co., Ltd. |
| | Yongin, Korea |
| TMPTA | Trimethylolpropane triacrylate, obtained under the trade |
| | designation “Miramer M300” from Miwon Specialty Chemical |
| | Co., Ltd. Yongin, Korea |
| MAAH | Methacrylic anhydride, obtained from Tokyo Chemical Industry, |
| | Tokyo, Japan |
| BA | Benzoic anhydride, obtained from Merck KGaA, Darmstadt, |
| | Germany |
| NBA | 5-Norbornene-2,3-dicarboxylic anhydride, obtained from Tokyo |
| | Chemical Industry, Tokyo, Japan |
| ECHMMA | 3,4-Epoxycyclohexylmethyl methacrylate, obtained under the trade |
| | designation “TTA-15” from Jiangsu Tetra New Material |
| | Technology, Shanghai, China |
| DCPA | Dicyclopentenyl acrylate, obtained under the trade designation |
| | “Etermer EM2051” from Eternal Materials Co., Ltd, Kaohsiung, |
| | Taiwan |
| DCC | N,N-Dicyclohexylcarbodiimide, obtained from Tokyo Chemical |
| | Industry, Tokyo, Japan |
| EGMMA | Ethylene glycol monoacetoacetate monomethacrylate, obtained |
| | from Tokyo Chemical Industry, Tokyo, Japan |
| BAPO | Bis(2,4,6-trimethylbenzoyl)phenylphosphine oxide, obtained under |
| | the trade designation “Omnirad 819” from IGM Resins, Waalwijk, |
| | the Netherlands |

### Test Methods

### Test Method 1: Film Preparation and Weight Change Test

A hexagonal slot (20 mm height×5 mm width×2 mm thickness) was carved on a Teflon block. The slot was filled with approximately 0.2 mL of an example or a comparative example composition. The Teflon block was placed in a small chamber connected to nitrogen. The top side of the chamber is transparent glass. The chamber was purged with nitrogen for 2 minutes. Then, 395 nm FJ800 UV LED lamp (Phoseon, OR, USA) was placed on the top glass side of the chamber, and the sample was exposed to 0.5 W/cm² for 20 seconds (total dosage 10 J/cm²). The cured film was detached from Teflon block with a stick or needle. The procedure was repeated to prepare 5 specimens.

A cured film was baked for 2 days at 85° C. to remove residual monomers or moisture, and was weighed (A). The film was kept in an oven set to 85° C., 85% relative humidity for 7 days, and was weighed (B). The film was baked again for 2 more days at 85° C. to remove physically adsorbed moisture, and was weighed (C). Water uptake was calculated according to following equations:

$$Maximum water uptake \% = ( B - A ) / A \times 100$$

$$Irreversible water uptake \% = ( C - A ) / A \times 100$$

### Test Method 2: pH Measurement of Liquid Samples

A 50 mL glass vial (30 mm diameter, 110 mm height) was filled with approximately 30 mL of a freshly prepared example or comparative example. The pH of the liquid was measured by S400 pH meter equipped with DGI116 organic solvent probe (Mettler Toledo, OH, USA). The probe was dipped into the vial, waited for 2 minutes and pH number was recorded.

To another 50 mL glass vial, approximately 30 mL of an example or comparative example and 1.5 mL of distilled water were added. The vial was placed in a water bath set to 50° C. for 7 days. The pH of the aged sample was measured in a same manner.

### Test Method 3: FT-IR

Chemical groups of a cured film were identified on Thermo iS50 FT-IR (Thermo Fisher, MA, USA) with Attenuated Total Reflectance method. A cured film before and after water uptake chamber test in Test Method 1 was pressed to the diamond prism and its IR spectrum was obtained by 32 scans with 4 nm resolution. A liquid sample droplet before and after water uptake test in Test Method 2 was dropped on the diamond prism and its IR spectrum was obtained in a same manner.

### Test Method 4: Refractive Index

Approximately 0.2 mL of an example was dropped on a clean glass substrate. Doctor blade was applicated to obtain approximately 5 μm-thick film. The film was cured in a nitrogen chamber described in Test Method 1 under 395 nm LED light (0.6 W/cm² for 5 sec=3 J/cm²). The refractive index of the cured film at 450 nm wavelength was measured on 2010M Prism Coupler (Metricon, NJ, USA).

### Test Method 5: Viscosity

A cylinder of which temperature was maintained at 25° C. was filled with approximately 20 mL of an example. Brookfield Viscometer LV-1 spindle (Ametek, PA, USA) was dipped into the cylinder and rotated at 6 rpm to obtain viscosity of the liquid.

### Test Method 6: OLED Lifetime Test

Strong cavity top emitting blue OLED coupons were fabricated using the SUNIC deposition system (SUNIC, Suwon, Korea). All layers in the OLED stack were thermally evaporated under vacuum. The thin film encapsulation structure was comprised of a bottom Al₂O₃ thin film, an organic ink layer, and a top Al₂O₃ thin film as shown in FIG. 1. Al₂O₃ layer was radio-frequency-sputtered using SUNIC deposition system and the organic ink was inkjet printed in nitrogen-filled glovebox (thickness 5 micrometers).

In FIG. 1, OLED 120 is located on base layer 110, with Al₂O₃ thin film 130, an organic ink layer 140, and a top Al₂O₃ thin film 150.

The OLED performance was first characterized before lifetime testing. Current-voltage-Luminance characteristics were recorded using a computer-controlled Keithley 2400 source meter and a calibrated PR650 spectrophotometer. Each OLED coupon has 4 active areas (or pixels) where light emission was measured. Nikon microscope was used to take images of the pixels. Pixel images were taken the first time before lifetime and accelerated reliability tests.

An OLED coupon was then loaded into the lifetime tester. Lifetime testing in OLA300 lifetime tester (S-fac, Daejon, Korea) was conducted at room temperature and relative humidity. Each OLED coupon was loaded into a testing cell, which applies a constant current to all four pixels throughout the duration of the test, and at the same time, measures the voltage and light output. Currents were selected and applied to the OLED coupon so the initial luminance of all pixels was approximately 100 cd/m². The luminance decay was monitored for each pixel, and the time required for luminance to drop to certain fraction of the initial luminance was recorded. For example, LT₉₀=time taken for luminance to drop 10% or become 90% of initial luminance. And LT₇₀=time taken for luminance to drop 30% or become 70% of initial luminance.

After 7 days of lifetime testing, coupons were removed from the tester. Images of all pixels were taken for the second time. Coupons were then loaded into a humidity chamber right after with preset temperature of 85° C. and relative humidity of 85%. After 24 hours, coupons were removed from the chamber, and images of pixels were taken for the last time.

### Test Method 7: Calcium WVTR Test

A similar coupon was prepared as shown in FIG. 2. On a glass sheet 210, Calcium metal 220 was vapor-deposited under vacuum to a thickness of 100 nanometers. Then aluminum oxide 130, cured organic layer of this disclosure 140, and another aluminum oxide layer 150 were deposited or printed. The sample was placed in an CTH chamber (85 C, 85% RH). The optical density was measured periodically. Doing so, water vapor transmission rate (WVTR) was calculated.

### Examples

A mixture of BPMA, TMPTA, BAPO and getter components indicated in Table 1 was stirred at 300 rpm for 10 min in a polyethylene bottle at room temperature placed under sodium light or white LED light, not under fluorescence lamp emitting ultraviolet light. Unless otherwise noted, all parts in the Examples and the rest of the specification are in grams.

TABLE 1

| Example | BPMA | TMPTA | BAPO | MAAH | MA | BA | NBA | ECHMMA | SUM |
|---|---|---|---|---|---|---|---|---|---|
| 1 | 61.3 | 25.0 | 2.0 | 3.9 | 0 | 0 | 0 | 9.8 | 102.0 |
| 2 | 47.7 | 25.0 | 2.0 | 7.7 | 0 | 0 | 0 | 19.6 | 102.0 |
| 3 | 34.0 | 25.0 | 2.0 | 11.6 | 0 | 0 | 0 | 29.4 | 102.0 |
| 4 | 20.3 | 25.0 | 2.0 | 15.5 | 0 | 0 | 0 | 39.2 | 102.0 |
| 5 | 62.8 | 25.0 | 2.0 | 0 | 2.5 | 0 | 0 | 9.8 | 102.0 |
| 6 | 50.5 | 25.0 | 2.0 | 0 | 4.9 | 0 | 0 | 19.6 | 102.0 |
| 7 | 38.2 | 25.0 | 2.0 | 0 | 7.4 | 0 | 0 | 29.4 | 102.0 |
| 8 | 25.9 | 25.0 | 2.0 | 0 | 9.9 | 0 | 0 | 39.2 | 102.0 |
| 9 | 37.9 | 25.0 | 2.0 | 7.7 | 0 | 0 | 0 | 29.4 | 102.0 |
| 10 | 53.8 | 25.0 | 2.0 | 1.6 | 0 | 0 | 0 | 19.6 | 102.0 |
| 11 | 28.6 | 25.0 | 2.0 | 0 | 0 | 17.0 | 0 | 29.4 | 102.0 |
| 12 | 33.2 | 25.0 | 2.0 | 0 | 0 | 0 | 12.4 | 29.4 | 102.0 |

Water uptake and pH measurements were carried out according to the test methods described above. The results are shown in Table 2 below.

TABLE 2

| | Maximum | Irreversible | | |
|---|---|---|---|---|
| | water uptake | water uptake | Initial pH | Final pH |
| | of the film | of the film | of the | of the |
| Example | (%) | (%) | liquid | liquid |
| 1 | 1.80 | 0.72 | 5.1 | 2.7 |
| 2 | 3.20 | 1.45 | 5.8 | 3.3 |
| 3 | 5.35 | 2.40 | 6.0 | 3.6 |
| 4 | 7.60 | 3.60 | 6.1 | 3.3 |
| 5 | 1.68 | 0.64 | 2.9 | 1.1 |
| 6 | 2.86 | 1.21 | 2.7 | 0.5 |
| 7 | 4.28 | 1.78 | 2.4 | 0.5 |
| 8 | 6.04 | 2.64 | 2.1 | 0.3 |
| 9 | 3.74 | 1.67 | 4.8 | 3.2 |
| 10 | 1.48 | 0.46 | 4.3 | 3.3 |
| 11 | 2.85 | 0.75 | 5.1 | 2.5 |
| 12 | 4.76 | 2.06 | 4.6 | 1.5 |

### Comparative Examples

A mixture of BPMA, TMPTA, BAPO and getter components indicated in Table 3 was stirred at 300 rpm for 10 min in a polyethylene bottle at room temperature placed under sodium light or white LED light, not under fluorescence lamp emitting ultraviolet light. Unless otherwise noted, all parts in the Examples and the rest of the specification are in gram.

TABLE 3

| Comp. | | | | | | | | | | |
|---|---|---|---|---|---|---|---|---|---|---|
| Example | BPMA | TMPTA | BAPO | MAAH | MA | ECHMMA | DCC | DCPA | EGMMA | SUM |
| A | 75.0 | 25.0 | 2.0 | 0 | 0 | 0 | 0 | 0 | 0 | 102.0 |
| B | 67.3 | 25.0 | 2.0 | 7.7 | 0 | 0 | 0 | 0 | 0 | 102.0 |
| C | 59.5 | 25.0 | 2.0 | 15.5 | 0 | 0 | 0 | 0 | 0 | 102.0 |
| D | 70.1 | 25.0 | 2.0 | 0 | 4.9 | 0 | 0 | 0 | 0 | 102.0 |
| E | 65.1 | 25.0 | 2.0 | 0 | 9.9 | 0 | 0 | 0 | 0 | 102.0 |
| F | 65.2 | 25.0 | 2.0 | 0 | 0 | 9.9 | 0 | 0 | 0 | 102.0 |
| G | 55.4 | 25.0 | 2.0 | 0 | 0 | 19.6 | 0 | 0 | 0 | 102.0 |
| H | 64.7 | 25.0 | 2.0 | 0 | 0 | 0 | 10.3 | 0 | 0 | 102.0 |
| I | 64.8 | 25.0 | 2.0 | 0 | 0 | 0 | 0 | 10.2 | 0 | 102.0 |
| J | 64.3 | 25.0 | 2.0 | 0 | 0 | 0 | 0 | 0 | 10.7 | 102.0 |
| K | 60.3 | 25.0 | 2.0 | 0 | 4.9 | 9.8 | 0 | 0 | 0 | 102.0 |
| L | 49.5 | 25.0 | 2.0 | 0 | 4.9 | 0 | 20.6 | 0 | 0 | 102.0 |
| M | 49.7 | 25.0 | 2.0 | 0 | 4.9 | 0 | 0 | 20.4 | 0 | 102.0 |
| N | 48.7 | 25.0 | 2.0 | 0 | 4.9 | 0 | 0 | 0 | 21.4 | 102.0 |
| O | 57.5 | 25.0 | 2.0 | 7.7 | 0 | 9.8 | 0 | 0 | 0 | 102.0 |
| P | 57.1 | 25.0 | 2.0 | 7.7 | 0 | 0 | 0 | 10.2 | 0 | 102.0 |
| Q | 46.9 | 25.0 | 2.0 | 7.7 | 0 | 0 | 0 | 20.4 | 0 | 102.0 |
| R | 36.7 | 25.0 | 2.0 | 7.7 | 0 | 0 | 0 | 30.6 | 0 | 102.0 |

Water uptake and pH measurements were carried out according to the test methods described above. The results are shown in Table 4 below.

TABLE 4

| | Maximum | Irreversible | | |
|---|---|---|---|---|
| | water uptake | water uptake | Initial pH | Final pH |
| Comp. | of the film | of the film | of the | of the |
| Example | (%) | (%) | liquid | liquid |
| A | 0.84 | 0.10 | Not measurable | 1.7 |
| B | 2.32 | 0.87 | 0.8 | 0.9 |
| C | 3.43 | 1.31 | 2.2 | 0.4 |
| D | 1.98 | 0.39 | 0.6 | 0.1 |
| E | 3.53 | 0.53 | 0.7 | 0.6 |
| F | 0.81 | 0.13 | 2.4 | 2.5 |
| G | 0.96 | 0.18 | 2.0 | 3.1 |
| H | 0.19 | −0.44 | 5.7 | 5.2 |
| I | 0.65 | 0.03 | 1.4 | 1.8 |
| J | −2.28 | −3.18 | 3.2 | 2.2 |
| K | 2.28 | 0.87 | 1.9 | 0.6 |
| L | Too brittle | Too brittle | 3.2 | Gelation |
| M | 1.76 | 0.46 | 0.9 | 0.4 |
| N | −4.54 | −6.52 | 1.6 | 0.4 |
| O | 2.63 | 1.16 | 5.1 | 2.1 |
| P | 2.35 | 0.85 | 3.1 | 0.7 |
| Q | 2.07 | 0.74 | 3.3 | 1.0 |
| R | 2.09 | 0.75 | 4.2 | 0.7 |

### Prophetic Examples

A mixture of BPMA, TMPTA, BAPO and moisture sequestration component indicated in Table 5 is stirred at 300 rpm for 10 min in a polyethylene bottle at room temperature placed under sodium light or white LED light, not under fluorescence lamp emitting ultraviolet light. Unless otherwise noted, all parts in the Examples and the rest of the specification are in gram.

### Materials Descriptions

| Abbre- | |
|---|---|
| viation | Description and Source |
| A-1 | Anhydride form of beta-carboxyethyl acrylate, internal |
| | preparation |
| A-2 | Anhydride form of mono-2-(methacryloxy)ethyl succinate, |
| | internal preparation |
| E-1 | 3,4-Epoxycyclohexylmethyl-3,4-epoxycyclohexanecarboxylate, |
| | obtained under the trade designation “TTA-21” from Jiangsu |
| | Tetra New Material Technology, Shanghai, China |
| E-2 | 1,2-Cyclohexanediol diglycidyl ether, obtained under the trade |
| | designation “TTA-118” from Jiangsu Tetra New Material |
| | Technology, Shanghai, China |
| E-3 | Resorcinol diglycidyl ether, obtained under the trade designation |
| | “TTA-320” from Jiangsu Tetra New Material Technology, |
| | Shanghai, China |
| E-4 | Trimethylolpropane triglycidyl ether, obtained under the trade |
| | designation “TTA-245” from from Jiangsu Tetra New Material |
| | Technology, Shanghai, China |

TABLE 5

| Prophetic | | | | | | | | | | | | |
|---|---|---|---|---|---|---|---|---|---|---|---|---|
| Example | BPMA | TMPTA | BAPO | MAAH | ECHMMA | A-1 | A-2 | E-1 | E-2 | E-3 | E-4 | SUM |
| P1 | 25.3 | 25.0 | 2.0 | 0 | 29.4 | 20.3 | 0 | 0 | 0 | 0 | 0 | 102.0 |
| P2 | 12.3 | 25.0 | 2.0 | 0 | 29.4 | 0 | 33.3 | 0 | 0 | 0 | 0 | 102.0 |
| P3 | 39.7 | 25.0 | 2.0 | 11.6 | 0 | 0 | 0 | 23.7 | 0 | 0 | 0 | 102.0 |
| P4 | 41.9 | 25.0 | 2.0 | 11.6 | 0 | 0 | 0 | 0 | 21.5 | 0 | 0 | 102.0 |
| P5 | 42.5 | 25.0 | 2.0 | 11.6 | 0 | 0 | 0 | 0 | 0 | 20.9 | 0 | 102.0 |
| P6 | 44.4 | 25.0 | 2.0 | 11.6 | 0 | 0 | 0 | 0 | 0 | 0 | 19.0 | 102.0 |

What is claimed is:

1. A curable ink composition comprising:
a (meth)acrylate-based component capable of curing to form a (meth)acrylate-based matrix, comprising:
at least one aromatic (meth)acrylate;
at least one multifunctional (meth)acrylate with heteroaromatic groups, fused aromatic groups, heteroalkylene groups, or a group containing both heteroalkylene and aromatic groups; and
a photoinitiator; and
a water sequestration component, the water sequestration component being a reactive pair, the reactive pair being epoxy-functional and anhydride-functional parts, wherein
the water sequestration component comprises:
at least one co-curable moiety comprising an epoxy-functional (meth)acrylate,
an anhydride-functional ethylenically unsaturated compound, or both; and
optionally a non-curable epoxy moiety, a non-curable anhydride moiety, or both;
such that upon curing, the ink composition forms a (meth)acrylate matrix wherein the (meth)acrylate matrix comprises epoxy-functional groups, anhydride-functional groups, or both, and wherein the (meth)acrylate matrix is capable of water sequestration whereby an anhydride group from either the co-curable moiety or the non-curable moiety, upon reacting with water forms acid-functional groups that react with epoxy-functional groups from either the co-curable moiety or the non-curable moiety creating irreversible water uptake of the (meth)acrylate-based matrix, wherein the ink composition is inkjet printable, having a viscosity of 30 centipoise or less at a temperature of from room temperature to 35° C., and is free from solvents, and wherein the ink composition when disposed and cured has a refractive index of 1.55 or greater, is optically clear, and has an irreversible water uptake of at least 2% by weight upon exposure to 85° C./85% Relative Humidity for 7 days.

2. The curable ink composition of claim 1, wherein the at least one aromatic (meth)acrylate comprises a monofunctional (meth)acrylate compound of Formula I: 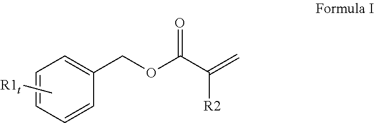
wherein at least one R1 comprises an aromatic substituent;
t is an integer from 1 to 4; and
R2 is hydrogen or methyl.

3. The curable ink composition of claim 2, wherein the at least one R1 group comprises: 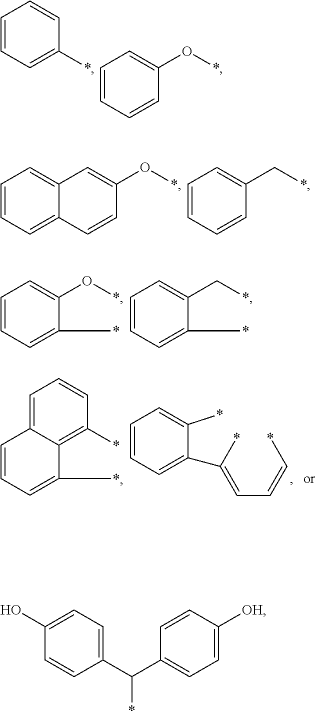
or *—S—Ar,
where each * denotes the point(s) of attachment to the aromatic ring of Formula I; and
Ar is a substituted or unsubstituted phenyl group, a fused aromatic group, or 2 or more alkyl group-linked phenyl or substituted phenyl or substituted phenyl groups.

4. The curable ink composition of claim 1, wherein the at least one multifunctional (meth)acrylate comprises a compound of Formula II:
(H₂C═CR2-(CO)—O-)ₙA Formula II
wherein R2 is hydrogen or methyl;
(CO) is a carbonyl group C═O; and
A is an n-valent group comprising a heteroaromatic group, a fused aromatic group, a heteroalkylene group, or a group containing both heteroalkylene and aromatic groups; and
n is an integer of 2 or greater.

5. The curable ink composition of claim 1, wherein at least a portion of the epoxy-functional part of the reactive pair of the water sequestration component comprises an epoxy-functional (meth)acrylate of Formula III:
H₂C═CR2-(CO)—O—CH₂—B Formula III
wherein R2 is hydrogen or methyl;
(CO) is a carbonyl group C═O; and
B is divalent group comprising an epoxy-functional alkylene or heteroalkylene group.

6. The curable ink composition of claim 1, wherein at least a portion of the anhydride-functional part of the reactive pair of the water sequestration component comprises an anhydride-functional ethylenically unsaturated group comprising:
a (meth)acrylate-functional anhydride of Formula IV:
H₂C═CR2-(CO)—O—(CO)—R2C═CH₂ Formula IV
wherein R2 is hydrogen or methyl;
(CO) is a carbonyl group C═O; or
maleic anhydride.

7. The curable ink composition of claim 1, wherein the water sequestration component further comprises a non-curable anhydride comprising an aromatic anhydride, or an aliphatic anhydride.

8. The curable ink composition of claim 1, wherein the water sequestration component comprises a co-curable epoxy-functional (meth)acrylate and a non-curable anhydride.

9. The curable ink composition of claim 8, wherein the epoxy-functional (meth)acrylate comprises 0.075-45% by weight of the total weight of the curable ink composition.

10. The curable ink composition of claim 8, wherein the non-curable anhydride comprises 0.005-18% by weight of the total weight of the curable ink composition.

11. An article comprising:
a substrate with a first major surface and a second major surface;
a cured organic layer adjacent to at least a portion of the second major surface of the substrate, wherein the cured organic layer comprises a crosslinked (meth)acrylate-based matrix containing at least one of epoxy-functional groups, anhydride-functional groups, or both, has a refractive index of 1.55 or greater, and is optically clear; and wherein the cured organic layer optionally comprises a non-curable epoxy moiety, a non-curable anhydride moiety, or both, such that the cured organic layer has a water sequestration component, the water sequestration component being a reactive pair, the reactive pair being epoxy-functional and anhydride-functional parts, whereby an anhydride group either cured into the (meth)acrylate matrix or a non-curable moiety, upon reacting with water forms acid-functional groups that react with epoxy-functional groups either cured into the (meth)acrylate matrix or a non-curable moiety, wherein at least one of the epoxy-functional or anhydride-functional groups is cured into the (meth)acrylate matrix, thereby creating irreversible water uptake of the (meth)acrylate-based matrix, wherein the irreversible water uptake is at least 2% by weight upon exposure to 85° C./85% Relative Humidity for 7 days.

12. The article of claim 11, wherein the cured organic layer comprises a curable ink composition that has been disposed and cured on at least a portion of the second major surface of the substrate,
wherein the curable ink composition comprises:
a (meth)acrylate-based component capable of curing to form a (meth)acrylate-based matrix, comprising:
at least one aromatic (meth)acrylate;
at least one multifunctional (meth)acrylate with heteroaromatic groups, fused aromatic groups, heteroalkylene groups, or a group containing both heteroalkylene and aromatic groups; and
a photoinitiator; and
a water sequestration component, the water sequestration component being a reactive pair, the reactive pair being epoxy-functional and anhydride-functional parts, wherein the water sequestration component comprises:
at least one co-curable moiety comprising an epoxy-functional (meth)acrylate, an anhydride-functional ethylenically unsaturated compound, or both; and
optionally a non-curable epoxy moiety, a non-curable anhydride moiety, or both;
wherein the curable ink composition is inkjet printable having a viscosity of 30 centipoise or less at a temperature of from room temperature to 35° C. and is free from solvents.

13. The article of claim 11, wherein the cured organic layer has a thickness of from 1-16 micrometers.

14. The article of claim 11, wherein the article comprises an electronic device and the substrate comprises an optical electronic component.

15. The article of claim 14, wherein the optical electronic component comprises an organic light emitting diode (OLED), a quantum dot light emitting diode, a micro light emitting diode, or a quantum nanorod electronic device.

16. The article of claim 12, wherein at least a portion of the epoxy-functional part of the reactive pair of the water sequestration component comprises an epoxy-functional (meth)acrylate of Formula III:
H₂C═CR2-(CO)—O—CH₂—B Formula III
wherein R2 is hydrogen or methyl;
(CO) is a carbonyl group C—O; and
B is divalent group comprising an epoxy-functional alkylene or heteroalkylene group.

17. The article of claim 12, wherein the anhydride-functional part of the reactive pair of the water sequestration component comprises an anhydride-functional ethylenically unsaturated group comprising:
a (meth)acrylate-functional anhydride of Formula IV:
H₂C═CR2-(CO)—O—(CO)—R2C═CH₂ Formula IV
wherein R2 is hydrogen or methyl;
(CO) is a carbonyl group C═O; or
maleic anhydride; or
a non-curable anhydride comprising an aromatic anhydride, or an aliphatic anhydride.

18. The article of claim 12, wherein the water sequestration component comprises a co-curable epoxy-functional (meth)acrylate and a non-curable anhydride.

19. The article of claim 18, wherein the epoxy-functional (meth)acrylate comprises 0.075-45% by weight of the total weight of the curable ink composition.

20. The article of claim 18, wherein the non-curable anhydride comprises 0.005-18% by weight of the total weight of the curable ink composition.
